(19) United States
(12) Patent Application Publication
(10) Pub. No.: US 2012/0176178 A1
(43) Pub. Date: Jul. 12, 2012

(54) SWITCH CIRCUIT CAPABLE OF PREVENTING VOLTAGE SPIKE, AND CONTROL METHOD AND LAYOUT STRUCTURE THEREOF

(76) Inventors: Tse-Lung Yang, Yunlin County (TW); Hsiang-Chung Chang, Hsinchu City (TW)

(21) Appl. No.: 13/177,503

(22) Filed: Jul. 6, 2011

(30) Foreign Application Priority Data
Jan. 6, 2011 (TW) 100100492

(51) Int. Cl. H03K 17/687; H01L 27/06

(52) U.S. Cl. 327/432; 257/378; 257/E27.015

(57) ABSTRACT

A switch circuit capable of preventing voltage spike, includes an input end for receiving an input voltage, an output end for outputting an output voltage, a switch unit for controlling an electrical connection between the input end and the output end according to a control signal, a protection unit for generating the control signal according to an input current passing through the input end, and a first parasitic transistor for controlling an electrical connection between a second end and a third end according to the control signal, wherein when the input current is greater than a threshold value, the switch unit turns off electrical connection between the input end and the output end according to the control signal, and the first parasitic transistor turns on electrical connection between the second end and the third end of first parasitic transistor according to the control signal to reduce variation of input current.

### BACKGROUND OF THE INVENTION

1. Field of the Invention

The present invention relates to a switch circuit and related control method and layout structure, and more particularly, to a switch circuit capable of preventing voltage spike and related control method and layout structure.

2. Description of the Prior Art

In general, power supplies are required for all electronic products to offer operating energy. Please refer to FIG. 1, which illustrates a schematic diagram of a power system 10 according to the prior art. In the power system 10, a power supply 102 is utilized for providing an input voltage VIN (not shown in FIG. 1). A switch circuit 104 receives an input voltage VIN via an input end IN and further controls whether to output an output voltage VO to an electronic product 100. However, since a short circuit condition occurs in the switch circuit 104, large short current may be introduced instantaneously. In other words, the input current IIN would become extremely large, damaging the internal components of the electronic product 100 or the power system 10.

To prevent the instantaneous large inrush current to damage the internal circuit components, the prior art often uses an over-current protection scheme to avoid undesired large current occurred in circuits. As shown in FIG. 2, the prior art may use a current limitation technique to limit the input current IIN within a specific value for over-current protection. However, in practice, a circuit response period is required for the over-current protection scheme to initial current limiting function when an over-current situation occurs. As shown in FIG. 2, during the period T1, the input current IIN is still increasing and may rise over a tolerance range of the circuit components. Until to the period T2, the input current IIN would be really limited under a specific value.

Thus, the prior art further provides a fast over-current protection method to improve the above-mentioned problem. Regarding the fast over-current protection method, as the input current IIN is greater than a predetermined threshold value during the period T1, the switch circuit 104 is turned off to break the input current IIN for enforcedly stopping the over-current situation. However, since the switch circuit 104 is turned off, the input current IIN and the input voltage VIN may drop sharply. For example, as shown in FIG. 2, the input current IIN drop from a large current value to zero in a short time during the period T1. In other words, the input current IIN may have great current variation instantaneously. In such a situation, please further refer to FIG. 1, the equivalent circuit between the power supply 102 and the input end IN is consisted of a line inductor Lwire, a line resistor Rwire and a power capacitor CVCC. Since the input current IIN have great current variation, the input voltage VIN would be sharply pulled up to maintain the continuity of the inductor current so that a serious voltage ripple effect occurs, also damaging the internal components of the electronic product 100 or the power system 10.

### SUMMARY OF THE INVENTION

It is therefore an objective of the present invention to provide a bias current control method and driving circuit.

The present invention discloses a switch circuit capable of preventing voltage spike, which includes an input end for receiving an input voltage; an output end for outputting an output voltage; a switch unit coupled to the input end and the output end for controlling an electrical connection between the input end and the output end according to a control signal; a protection unit coupled to the input end for generating the control signal according to an input current passing through the input end; and a first parasitic transistor comprising a first end coupled to the protection unit for receiving the control signal, a second end coupled to the input end, and a third end coupled to a reference potential end for controlling an electrical connection between the second end and the third end according to the control signal; wherein when the input current is greater than a threshold value, the switch unit turns off the electrical connection between the input end and the output end according to the control signal, and the first parasitic transistor turns on the electrical connection between the second end and the third end of the first parasitic transistor according to the control signal to reduce variation of the input current.

The present invention further discloses a control method capable of preventing voltage spike for a switch unit, the switch unit receiving an input voltage via an input end and outputting an output voltage via an output end, the control method includes turning off an electrical connection between the input end and the output end when an input current passing through the input end is greater than a threshold value; and turning on a first parasitic transistor so that the input current is capable of passing through the first parasitic transistor to create a current path for reducing variation of the input current.

The present invention further discloses a layout structure, which includes a P-type semiconductor substrate; a buried layer, disposed on the P-type semiconductor substrate; a P well, disposed on the buried layer; an N-type drain doped region, disposed in the P well; and an N-type source doped region, disposed in the P well; wherein the N-type drain doped region, the buried layer, and the P well form a first parasitic transistor.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a schematic diagram of a power system according to the prior art.

FIG. 2 illustrates a schematic diagram of signal waveforms of the input current shown in FIG. 1.

FIG. 3 illustrates a schematic diagram of a switch circuit according to an embodiment of the present invention.

FIG. 4 illustrates a schematic diagram of a switch circuit according to an alternative embodiment of the present invention.

FIGS. 5A and 5B are schematic diagrams of signal waveforms of the input voltage and the input current during the operation of the switch unit according to embodiments of the present invention respectively.

FIG. 6 illustrates a schematic diagram of a procedure according to an embodiment of the present invention.

FIG. 7 illustrates a schematic diagram illustrating a cross-sectional view of a layout structure of the switch unit shown in FIG. 3.

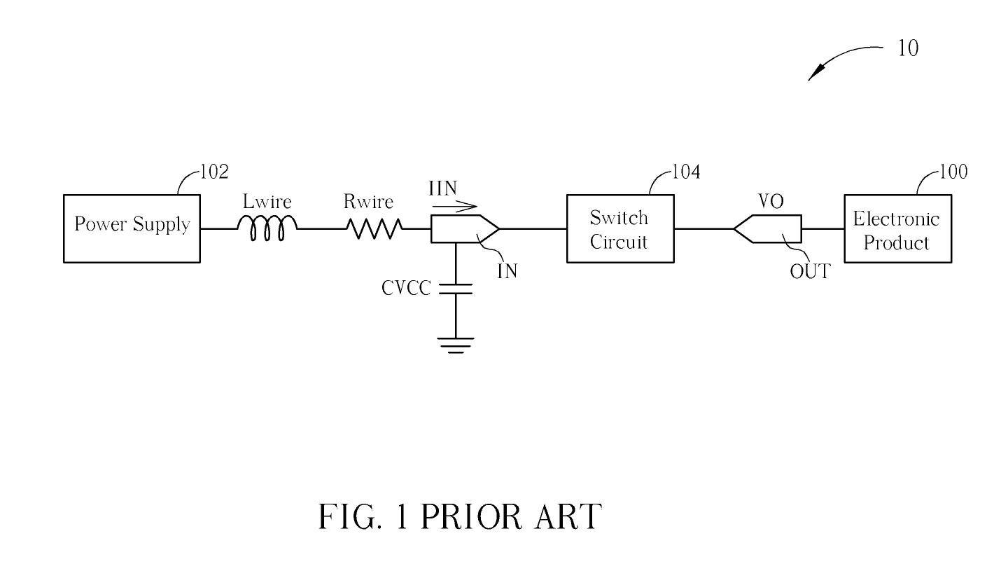

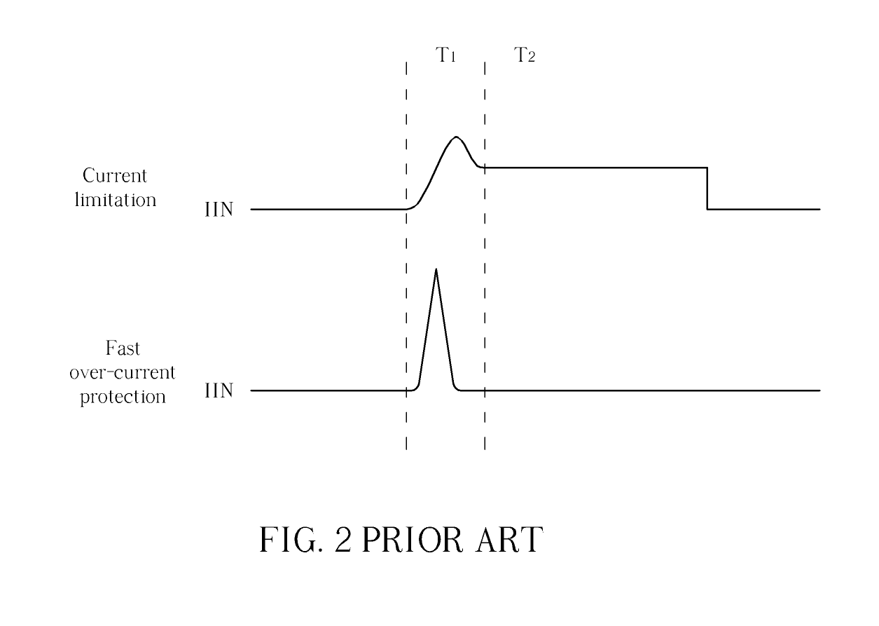

### DETAILED DESCRIPTION

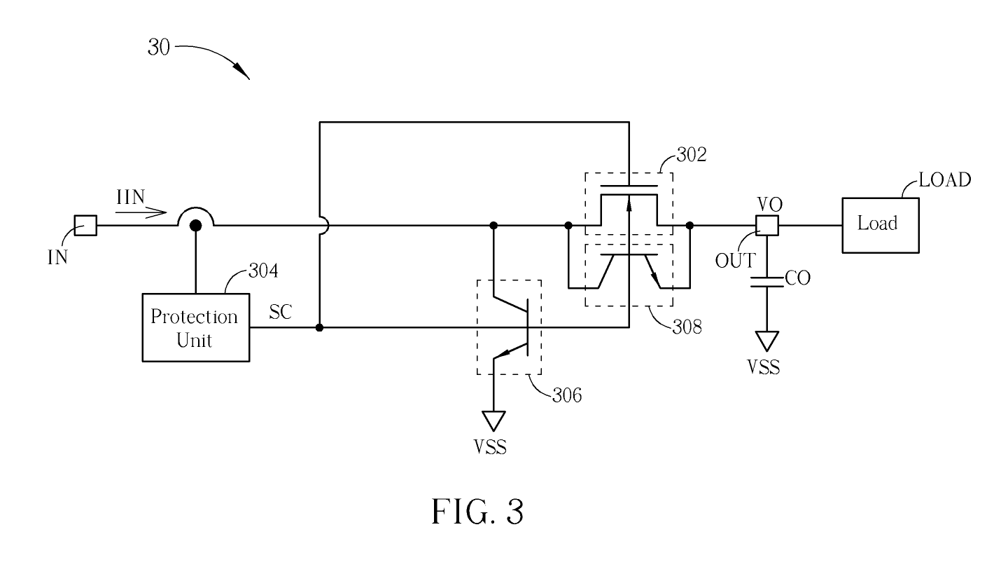

Please refer to FIG. 3, which illustrates a schematic diagram of a switch circuit 30 according to an embodiment of the present invention. The switch circuit 30 is utilized for receiving an input voltage VIN and outputting an output voltage VO to a load LOAD. The switch circuit 30 includes an input end IN, an output end OUT, a switch unit 302, a protection unit 304, a first parasitic transistor 306, a second parasitic transistor 308, and an output capacitor CO. The input end IN is utilized for receiving the input voltage VIN. The output end OUT is utilized for outputting the output voltage VO. The switch unit 302 is coupled to the input end VIN and the output end OUT for controlling an electrical connection between the input end IN and the output end OUT according to a control signal SC. In other words, the switch unit 302 can control the electrical connection between the input end IN and the output end OUT according to circuit system requirement during normal operation, and further control the electrical connection between the input end IN and the output end OUT through the control scheme of the control signal SC to avoid occurrence of ripple voltage of power. As shown in FIG. 3, the switch unit 302 is preferably a metal oxide semiconductor (MOS) transistor, and this should not be a limitation of the invention. The protection unit 304 is coupled to the input end IN for generating the control signal SC according to an input current IIN passing through the input end IN. The base of the first parasitic transistor 306 is coupled to the protection unit 304 for receiving the control signal SC, the collector of the first parasitic transistor 306 is coupled to the input end IN, and the emitter of the first parasitic transistor 306 is coupled to a reference potential end VSS. In other words, the first parasitic transistor 306 is utilized for controlling an electrical connection between the collector and the emitter of the first parasitic transistor 306 according to the control signal SC. The base of the second parasitic transistor 308 is coupled to the protection unit 304 for receiving the control signal SC, the collector of the second parasitic transistor 308 is coupled to the input end IN, and the emitter of the second parasitic transistor 308 is coupled to the output end OUT. In other words, the second parasitic transistor 308 is utilized for controlling an electrical connection between the collector and the emitter of the second parasitic transistor 308 according to the control signal SC.

Therefore, when the input current IIN is greater than a threshold value TH, the switch unit 302 can break the electrical connection between the input end IN and the output end OUT according to the control signal SC. Moreover, the first parasitic transistor 306 can turn on the electrical connection between its collector and its emitter according to the control signal SC. As a result, after the electrical connection between the input end IN and the output end OUT is turned off, the large current variation of the input current IIN will not occur instantaneously so as to avoid occurrence of voltage spike.

Furthermore, to prevent the instantaneous large current spike from damaging the circuit components or the electronic products, the protection unit 304 generates the control signal SC to the switch unit 302 when the input current IIN is greater than the threshold value TH. Thus, the switch unit 302 turns off the electrical connection between the input end IN and the output end OUT accordingly. Meanwhile the protection unit 304 can also transmit the control signal SC to the base of the first parasitic transistor 306 so as to cause the first parasitic transistor 306 to conduct. Therefore, the input current IIN is capable of passing through the first parasitic transistor 306 for creating another current path. In such a situation, although the switch unit 302 has broken the electrical connection between the input end IN and the output end OUT, the first parasitic transistor 306 can offer another current path for the input current IIN. Therefore, the input current IIN is able to flow through the first parasitic transistor 306 without occurrence of current interruption. In brief, since the instantaneous large current spike occurs, the protection unit 304 can control the switch unit 302 to turn off the electrical connection between the input end IN and the output end OUT through the control signal SC. Simultaneously, the protection unit 304 can also control to conduct the first parasitic transistor 306 by the control signal SC to create another current path for the input current IIN so that the input current IIN can keep to flow in the circuit, thus reducing variation of the input current IIN and occurrence of voltage spike.

On the other hand, when the input current IIN is greater than a threshold value TH, the protection unit 304 can also conduct the second parasitic transistor 308 by the control signal SC so that the input current IIN will has much less variation accordingly, further reducing occurrence of voltage spike . In addition, since the switch unit 302 is turned on, the output capacitor CO starts charging. Thus, when the switch unit 302 is turned off, the output capacitor CO may also hold a certain amount of electrical charge. Meanwhile, the output voltage VO is still greater than a voltage value of the voltage reference potential end VSS. In other words, the current passing through the second parasitic transistor 308 may be less than the current passing through the first parasitic transistor 306 so that the switch unit 302 will not be damaged accordingly.

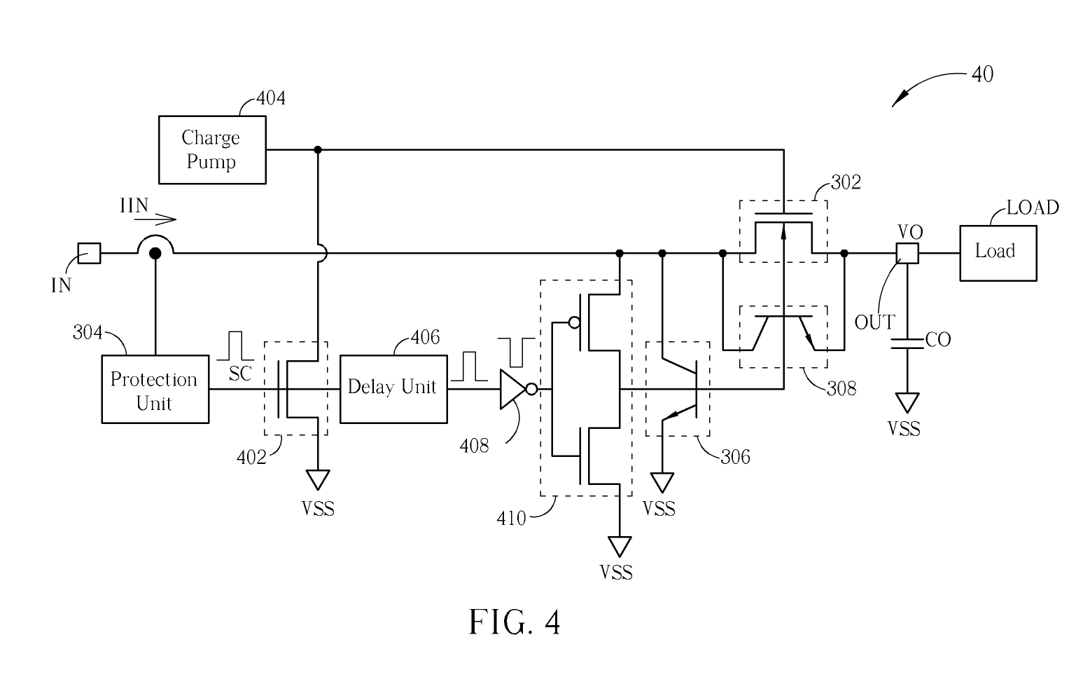

Please refer to FIG. 4, which illustrates a schematic diagram of a switch circuit 40 according to an alternative embodiment of the present invention. The switch circuit 40 includes an input end IN, an output end OUT, a switch unit 302, a protection unit 304, a transistor 402, a charge pump 404, a delay unit 406, an inverter 408, a CMOS inverter 410, a first parasitic transistor 306, a second parasitic transistor 308, and an output capacitor CO. The switch unit 302 can be an MOS transistor, and this should not be a limitation of the invention. When a short circuit condition occurs, the input current IIN may be sharply pulled up in a short time. In such a condition, when the protection unit 304 detects that the input current IIN is greater than the threshold value TH, the protection unit 304 generates the control signal SC to cause the transistor 402 to conduct. After the transistor 402 is turned on, the voltage at the gate of the switch unit 302 may be pulled down to zero potential (or ground potential) and the switch unit 302 changes to an off state accordingly. At this time, the input current IIN and the input voltage VIN are pulled down instantaneously. Moreover, as shown in FIG. 4, the control signal SC can be transmitted to the transistor 402 and the delay unit 406 at the same time. After being performed a delay process by the delay unit 406 and performed a buffer process by the inverter 408 and the CMOS inverter 410 respectively, the control signal SC can further transmit to the base of the first parasitic transistor 306 and the base of the second parasitic transistor 308 to cause the first parasitic transistor 306 and the second parasitic transistor 308 to conduct. In such a situation, the input current IIN can flow through the first parasitic transistor 306 and the second parasitic transistor 308 to obtain new current path so as to timely reduce variation of current, preventing occurrence of voltage spike.

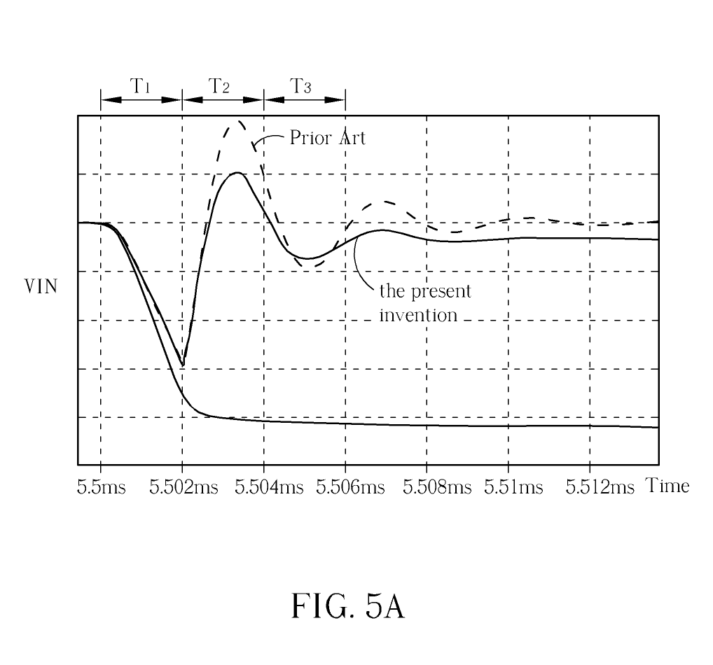

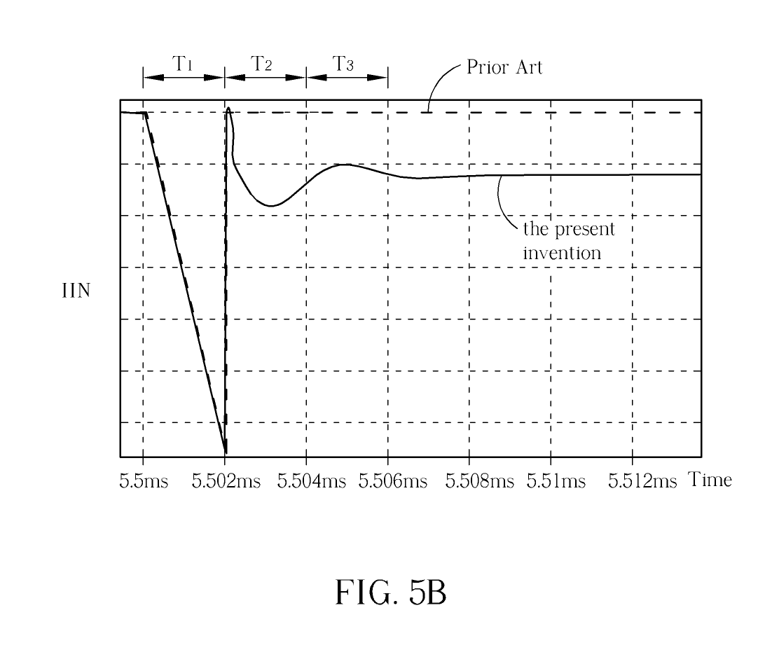

Please refer to FIGS. 5A and 5B, which are schematic diagrams of signal waveforms of the input voltage VIN and the input current IIN during the operation of the switch unit 40 according to an embodiment of the present invention respectively. The dashed line represents signal waveform of the prior art, and the solid line represents signal waveform of the embodiment of the invention. As shown in FIGS. 5A ad 5B, since a short circuit condition occurs in the switch unit 40 during the period T1, the input voltage VIN and the input current IIN drop immediately. During the period T2, rebound range of both the input voltage VIN and the input current IIN of the embodiment of the invention are smaller than the rebound range of the prior art. As a result, the invention can actually reduce the variation of current and voltage for preventing occurrence of voltage spike.

Note that, the exemplary embodiments shown in FIGS. 3 and 4 illustrate that the switch unit 302 is realized by an N-type MOS transistor, and those skilled in the art can make alternations and modifications accordingly. For example, the switch unit 302 can also realized by a P type MOS transistor, a combination circuit of multiple transistors, or other switch circuit, so as not to be narrated herein.

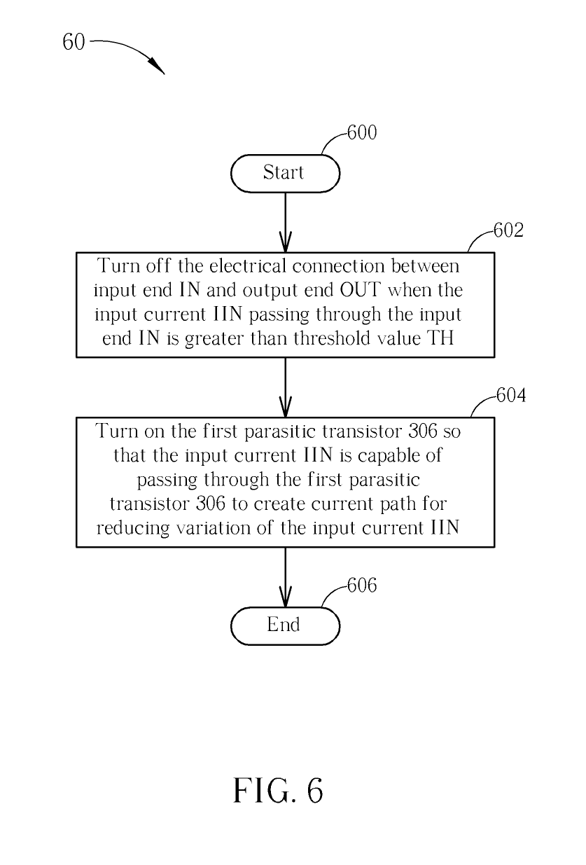

Furthermore, operations of the switch circuits 30 and 40 may be summarized in a procedure 60 as shown in FIG. 6. The procedure 60 includes the following steps:

Step 600: Start.

Step 602: Turnoff the electrical connection between input end IN and output end OUT when the input current IIN passing through the input end IN is greater than a threshold value TH.

Step 604: Turn on the first parasitic transistor 306 so that the input current IIN is capable of passing through the first parasitic transistor 306 to create a current path for reducing variation of the input current IIN.

Step 606: End.

Related variations and the detailed description of the procedure 60 can be referred from the foregoing description, so as not to be narrated herein.

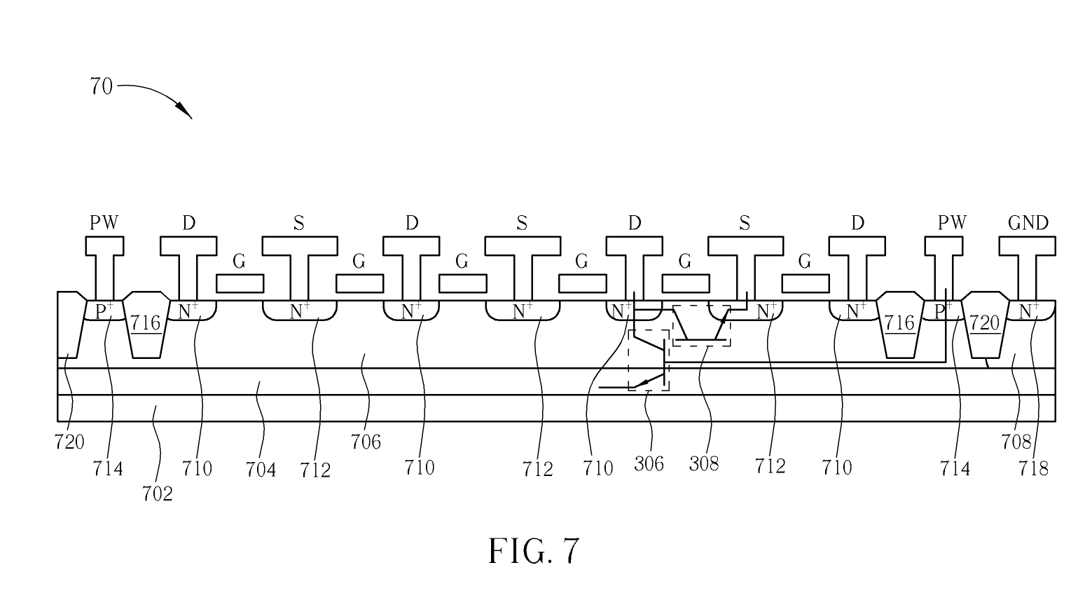

Moreover, please refer to FIG. 7, which is a schematic diagram illustrating a cross-sectional view of a layout structure 70 of the switch unit 302 shown in FIG. 3. Take the switch unit 302 as an N-type metal oxide semiconductor (MOS) transistor for example, the layout structure 70 includes a P-type semiconductor substrate 702, a buried layer 704, a P well 706, an N well 708, an N-type drain doped region 710, an N-type source doped region 712, a P-type body contact doped region 714, a first isolation region 716, an N-type doped region 718, a second isolation region 720, a ground electrode GND, gate electrodes G, drain electrodes D, source electrodes G, and control electrodes PW.

The buried layer 704 is disposed on the P-type semiconductor substrate 702. The P well 706 and the N well 708 are disposed on the buried layer 704. The N-type drain doped region 710 and the N-type source doped region 712 are disposed in the P well 706. The P-type body contact doped region 714 is disposed in the P well 706. The first isolation region 716 is utilized for isolating the P-type body contact doped region 714 and the N-type drain doped region 710. The N-type doped region 718 is disposed in the N well 708. The second isolation region 720 is utilized for isolating the N-type doped region 718 and P-type body contact doped region 714. The ground electrode GND is disposed on the N-type doped region 718. The control electrode PW is disposed on the P-type body contact doped region 714. The drain electrode D is disposed on the N-type drain doped region 710. The source gate electrode S is disposed on the N-type source doped region 712. Each N-type drain doped region 710, the buried layer 704 and the P well 706 are together capable of forming a first parasitic transistor 306. Each N-type drain doped region 710, the N-type source doped region 712 and the P well 706 are together capable of forming a second parasitic transistor 308. As shown in FIG. 7, the base of the first parasitic transistor 306 and the base of the second parasitic transistor 308 are connected together. In such a situation, when the control electrode PW is connected to the protection unit 304, the on/off state of the first parasitic transistor 306 and the second parasitic transistor 308 can be controlled by the control signal SC to lead current to flow through the first parasitic transistor 306 and the second parasitic transistor 308.

In summary, the invention can utilize the parasitic transistor of the semiconductor timely to create another current path for preventing occurrence of voltage spike and damage of the components of the electronic effectively.

Those skilled in the art will readily observe that numerous modifications and alterations of the device and method may be made while retaining the teachings of the invention.

What is claimed is:

1. A switch circuit capable of preventing voltage spike, comprising:
an input end for receiving an input voltage;
an output end for outputting an output voltage;
a switch unit coupled to the input end and the output end for controlling an electrical connection between the input end and the output end according to a control signal;
a protection unit coupled to the input end for generating the control signal according to an input current passing through the input end; and
a first parasitic transistor comprising a first end coupled to the protection unit for receiving the control signal, a second end coupled to the input end, and a third end coupled to a reference potential end for controlling an electrical connection between the second end and the third end according to the control signal;
wherein when the input current is greater than a threshold value, the switch unit turns off the electrical connection between the input end and the output end according to the control signal, and the first parasitic transistor turns on the electrical connection between the second end and the third end of the first parasitic transistor according to the control signal to reduce variation of the input current.

2. The switch circuit of claim 1, further comprising:
a second parasitic transistor comprising a first end coupled to the first end of the first parasitic transistor for receiving the control signal, a second end coupled to the input end, and a third end coupled to output end, for controlling an electrical connection between the second end and the third end of the second parasitic transistor according to the control signal.

3. The switch circuit of claim 1, further comprising:
an output capacitor coupled to the output end and the reference potential end.

4. The switch circuit of claim 1, wherein the switch unit is a metal-oxide-semiconductor transistor comprising a first end, a second end coupled to the input end, and a third end coupled to the output end.

5. The switch circuit of claim 1, wherein the reference potential end is a ground end.

6. A control method capable of preventing voltage spike for a switch unit, the switch unit receiving an input voltage via an input end and outputting an output voltage via an output end, the control method comprising:
turning off an electrical connection between the input end and the output end when an input current passing through the input end is greater than a threshold value; and
turning on a first parasitic transistor so that the input current is capable of passing through the first parasitic transistor to create a current path for reducing variation of the input current.

7. The control method of claim 6, further comprising:
detecting the input current passing through the input end.

8. The control method of claim 6, wherein the step of turning off the electrical connection between the input end and the output end when the input current passing through the input end is greater than the threshold value comprises:
generating a control signal when the input current is greater than the threshold value; and
turning off the electrical connection between the input end and the output end according to the control signal.

9. The control method of claim 8, wherein the step of turning on the first parasitic transistor so that the input current is capable of passing through the first parasitic transistor to create the current path for reducing variation of the input current comprises:
turning on the first parasitic transistor so that the input current is capable of passing through the first parasitic transistor to create the current path according to the control signal for reducing variation of the input current.

10. A layout structure, comprising:
a P-type semiconductor substrate;
a buried layer, disposed on the P-type semiconductor substrate;
a P well, disposed on the buried layer;
an N-type drain doped region, disposed in the P well; and
an N-type source doped region, disposed in the P well;
wherein the N-type drain doped region, the buried layer, and the P well form a first parasitic transistor.

11. The layout structure of claim 10, further comprising:
a gate electrode;
a drain electrode, disposed on the N-type drain doped region; and
a source electrode, disposed on the N-type source doped region.

12. The layout structure of claim 10, further comprising:
a P-type body contact doped region, disposed in the P well;
a first isolation region, for isolating the P-type body contact doped region and the N-type drain doped region; and
a control electrode, disposed on the P-type body contact doped region.

13. The layout structure of claim 10, further comprising:
an N well, disposed on the buried layer; and
an N-type doped region, disposed in the N well; and
a second isolation region, for isolating the N-type doped region and P-type body contact doped region.

14. The layout structure of claim 13, further comprising:
a ground electrode, disposed on the N-type doped region.

15. The layout structure of claim 10, wherein the N-type drain doped region, the N-type source doped region, and the P well forma second parasitic transistor.

16. The layout structure of claim 15, wherein the first parasitic transistor and the second parasitic transistor are bipolar junction transistors.
